(19) United States
(12) Patent Application Publication
(10) Pub. No.: US 2026/0141949 A1
(43) Pub. Date: May 21, 2026

(54) Memory With Selective Negative Bit Line Boost

(71) Applicant: QUALCOMM Incorporated, San Diego, CA (US)

(72) Inventors: Keejong KIM, San Diego, CA (US); Anil Chowdary KOTA, San Diego, CA (US); Jung Pill KIM, San Diego, CA (US); Chulmin JUNG, San Diego, CA (US)

(21) Appl. No.: 18/949,867

(22) Filed: Nov. 15, 2024

(51) Int. Cl. G11C 11/419; G11C 11/412

(52) U.S. Cl. CPC G11C 11/419; G11C 11/412

(57) ABSTRACT

A memory is provided that is includes a sense amplifier for sensing a bit during a write operation. The memory further includes a selective negative bit line boost enable circuit that uses the sense amplifier during a write operation to compare a charged bit line to a reference voltage. Depending upon the comparison, the sense amplifier either asserts or de-asserts a negative bit line boost enable signal.

### TECHNICAL FIELD

This application relates to memories, and more particularly to a memory with a selective negative bit line boost operation.

### BACKGROUND

A static random-access memory (SRAM) bitcell includes a pair of cross-coupled inverters. Depending upon the binary state of a stored data bit, a p-type metal-oxide semiconductor (PMOS) transistor in one of the cross-coupled inverters charges a data node to a memory power supply voltage. During a write operation in which the binary content of the bitcell is changed, an n-type metal-oxide semiconductor (NMOS) access transistor functions to discharge the same data node to a grounded bit line while the PMOS transistor continues to charge the data node. The resulting NMOS/PMOS struggle slows the write operation speed and consumes power.

### SUMMARY

In accordance with an aspect of the disclosure, a memory is provided that includes: a column of bitcells including a bit line and a complement bit line; a write driver configured to drive the bit line and the complement bit line responsive to a data input signal; a negative bit line boost circuit configured to charge a negative boost node of the write driver to a negative voltage responsive to an assertion of a boost enable signal; and a sense amplifier configured to assert the boost enable signal responsive to a voltage of a charged one of the bit line and the complement bit line having less than a threshold voltage decrease during a write operation, the sense amplifier being further configured to not assert the boost enable signal responsive to the voltage of the charged one of the bit line and the complement bit line having greater than the threshold voltage decrease during the write operation.

In accordance with another aspect of the disclosure, a selective negative bit line boost method of operation for a memory is provided that includes: charging a first bit line in a bit line pair through a write driver during a write operation while discharging a second bit line in the bit line pair through the write driver; asserting a boost enable signal during a negative bit line boost enable period of the write operation responsive to a voltage of the first bit line being less than a reference voltage; and applying a negative voltage to the second bit line during the negative bit line boost enable period responsive to the asserting of the boost enable signal.

Finally, in accordance with another aspect of the disclosure, a memory is provided that includes: a bit line pair including a first bit line and a second bit line; a sense amplifier having a first input node and a second input node; a reference voltage source; a first transistor coupled between the reference voltage source and the first input node; a second transistor coupled between the reference voltage source and the second input node; a third transistor coupled between the first bit line and the first input node; and a fourth transistor coupled between the second bit line and the second input node.

These and additional advantageous features may be better appreciated through the following detailed description.

### BRIEF DESCRIPTION OF THE DRAWINGS

FIG. 1 is a timing diagram of some memory signals during a write operation in which a negative bit line boost operation is suppressed in accordance with an aspect of the disclosure.

FIG. 2 illustrates is a timing diagram of some memory signals during a write operation in which a negative bit line boost operation is not suppressed in accordance with an aspect of the disclosure.

FIG. 3 is a schematic diagram of a memory including a selective negative bit line boost enable circuit in accordance with an aspect of the disclosure.

FIG. 4 is a circuit diagram for the selective negative bit line boost enable circuit of FIG. 3 in accordance with an aspect of the disclosure.

FIG. 5 is a timing diagram of some signals for the circuit of FIG. 4 during a write operation in which a negative bit line boost operation is suppressed in accordance with an aspect of the disclosure.

FIG. 6 is a timing diagram of some signals for the circuit of FIG. 4 during a write operation in which a negative bit line boost operation is not suppressed in accordance with an aspect of the disclosure.

FIG. 7 is a circuit diagram of an example negative bit line boost circuit for the memory of FIG. 3.

FIG. 8 is a schematic diagram of a memory including a selective negative bit line boost enable circuit in accordance with an aspect of the disclosure.

FIG. 9 is a circuit diagram of the selective negative bit line boost enable circuit of FIG. 8 in accordance with an aspect of the disclosure.

FIG. 10 is a timing diagram for some signals of the memory of FIG. 8 for a write operation in which the data input signal is a binary zero in accordance with an aspect of the disclosure.

FIG. 11 is a timing diagram for some signals of the memory of FIG. 8 for a write operation in which the data input signal is a binary one in accordance with an aspect of the disclosure.

FIG. 12 is a flowchart for a selective negative bit line boost method of operation for a memory in accordance with an aspect of the disclosure.

FIG. 13 illustrates some example electronic systems including an integrated circuit having a memory with selective negative bit line boosting in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

To increase the memory speed by addressing the NMOS/PMOS struggle that may delay completion of a write operation, the size of the NMOS access transistors could be increased as compared to the size of the PMOS bitcell transistors. But the increased transistor size then demands more semiconductor die space, which increases cost. To avoid this die space demand, SRAMs may use a negative bit line write assist. With regard to this technique, a write operation may involve changing the binary content of a bitcell such that a data node that is being charged by a PMOS transistor in one of the bitcell's cross-coupled inverters must be discharged to a grounded bit line during the write operation through an NMOS access transistor. Using a negative bit line boost circuit, the discharged one of the bit lines in the bit line pair is not only grounded but then pulled to a negative voltage during the write operation. This negative voltage on the bit line effectively increases the strength of the NMOS access transistor with respect to its struggle with the PMOS transistor that would otherwise continue to charge the data node to a memory power supply voltage. The increased effective strength of the NMOS access transistor allows it to more quickly discharge the data node so that the write operation speed is increased accordingly. Without the negative bit line boost, the NMOS access transistors may need to be sized larger, which increases the memory footprint on the semiconductor die and thus raises manufacturing costs. But with the negative bit line boost, the NMOS access transistor may be relatively smaller, which decreases the amount of semiconductor die space occupied by the memory and thus lowers manufacturing costs.

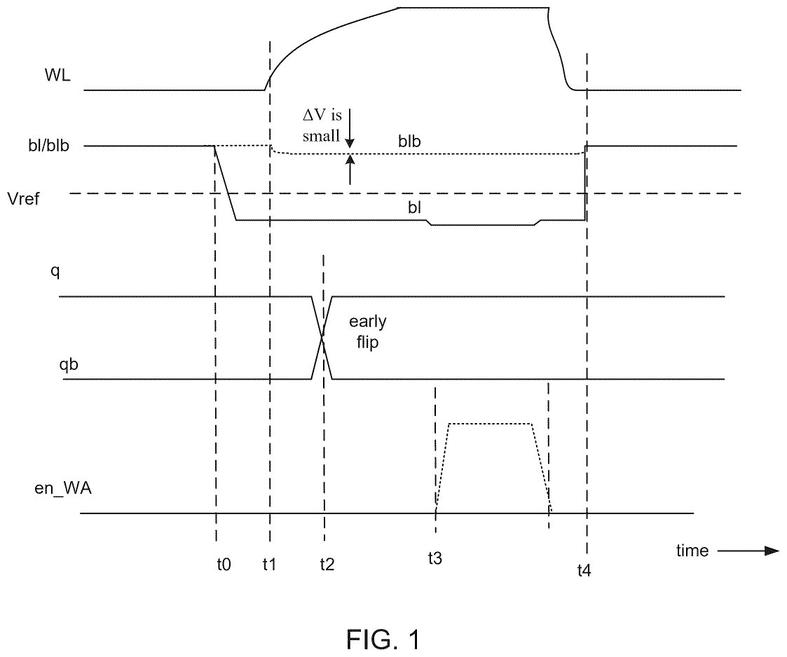

Although SRAMs with negative bit line boost are thus advantageous, the need for a negative bit line boost typically depends on the process corner used during manufacture of the semiconductor die that incorporates the SRAM. In addition, the power supply voltage and the temperature also affects the need for a negative bit line boost. In general, the majority of the process, voltage, and temperature corners for an SRAM will not require negative bit line boosting. This may be better understood with reference to the timing diagram of FIG. 1 for some memory operating signals with negative bit line boost. Prior to a write operation beginning at a time t0, a bit line bl and a complement bit line blb for an accessed column are both precharged to a memory power supply voltage. At time t0, a write driver (not illustrated) discharges the bit line bl while maintaining the charge of the complement bit line blb. More generally, one of the bit lines in a bit line pair is discharged while a remaining one of the bit lines in the bit line pair remains charged. At a time t1, a memory controller (not illustrated) asserts a word line (WL) voltage to switch on the access transistors to the accessed bitcell. In this example, it is assumed that the accessed bitcell is storing a binary zero prior to the write operation such that its complement bit node qb is grounded whereas its bit node q is charged to the memory power supply voltage. The discharged complement bit node qb thus causes a slight decrease ΔV in the complement bit line blb voltage after the word line voltage is asserted at time t1. Since the voltage difference between the q and qb nodes is nearly full rail (the difference being nearly equal to the power supply voltage), the write operation is successful (early flip) at a time t2 that is before the assertion of a boost enable signal en_WA at a time t3. During the assertion of the boost enable signal en_WA, a negative bit line boost circuit may apply a negative boost to the bit line bl such that the bit line voltage is decreased below zero. But since the bitcell flip occurred prior to the assertion of the boost enable signal en_WA, the negative bit line boost for the write operation was unnecessary. At a time t4, the write operation is completed so that the bit line bl and complement bit line blb are pre-charged back to the memory power supply voltage.

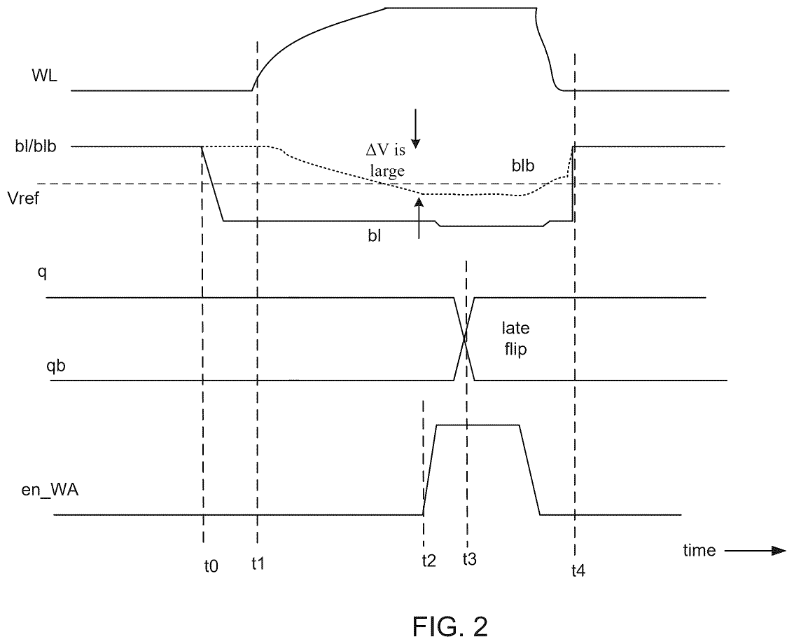

A timing diagram in which a successful write operation requires a negative bit line boost is shown in FIG. 2. The write operation begins at a time t0 as discussed with regard to FIG. 1. Similarly, the word line WL voltage is asserted at a time t1. But in FIG. 2, the discharged complement bit node qb causes a relatively large decrease ΔV in the complement bit line blb voltage after the word line voltage is asserted at time t1. The resulting difference between the bit line bl voltage and the complement bit line voltage blb is thus relatively small such that the bitcell's binary content does not flip prior to the assertion of the negative bit line boost enable signal en_WA at a time t2. The bitcell does not flip until a time t3 after the assertion of the boost enable signal en_WA. The write operation then completes at a time t4.

Since the majority of the process corners will lead to an early bitcell flip as discussed with regard to FIG. 1, the negative bit line boost is undesirably consuming power without providing any benefit. However, a memory manufacturer cannot guarantee the process corner. A memory as discussed with regard to FIG. 2 may then have a write error if the negative bit line boost is not applied. Yet the negative bit line boost then consumes power needlessly for the bulk of the process corners. A selective negative bit line boost enable circuit is thus disclosed that enables the negative bit line boost only when necessary. For the majority of the process corners, the selective negative bit line boost enable circuit thus suppresses the negative bit line boost so as to save power. But if the process corner is such that negative bit line boost is necessary for a successful write operation, the selective negative bit line boost enable circuit enables the negative bit line boost.

The selection between enabling or disabling the negative bit line boost by the selective negative bit line boost enable circuit may be performed by monitoring the voltage decline (ΔV) on the bit line that should remain charged during the write operation. Referring again to FIGS. 1 and 2, it may be seen that it was the complement bit line blb that was to remain charged, but this depends upon the binary value of the bit being written during the write operation and whether the write driver inverts the data bit being written to the bitcell. In the following discussion, the bit line that should remain charged is denoted as the charged bit line whereas the remaining bit line in the accessed bit line pair is denoted as the discharged bit line. The selective negative bit line boost enable circuit may thus monitor the voltage decrease (ΔV) of the charged bit line during the write operation. Should the voltage decrease be relatively small such as discussed with respect to FIG. 1, the selective negative bit line boost enable circuit does not enable a negative bit line boost during the write operation. But if the voltage decrease is relatively large such as discussed with respect to FIG. 2, the selective negative bit line boost enable circuit enables a negative bit line boost.

The selective negative bit line boost enable circuit disclosed herein may thus compare the voltage for the charged bit line to a reference voltage to either enable or suppress a negative bit line boost during a write operation. For example, consider again the early flip timing of FIG. 1. A reference voltage Vref equals approximately one-half of the memory power supply voltage although the reference voltage level may be varied in alternative implementations. The selective negative bit line boost enable circuit disclosed herein compares the voltage of the charged bit line at time t3 to the reference voltage. Since the charged bit line voltage is greater than the reference voltage at time t3, the selective negative bit line boost enable circuit suppresses the assertion of the boost enable signal en_WA. The assertion of the boost enable signal en_WA is thus shown in FIG. 1 using a dotted line as in reality it was suppressed. In contrast, the charged bit line voltage in the late flip timing of FIG. 2 at time t2 has dropped below the reference voltage. In response, the selective negative bit line boost enable circuit does not suppress the assertion of the boost enable signal en_WA.

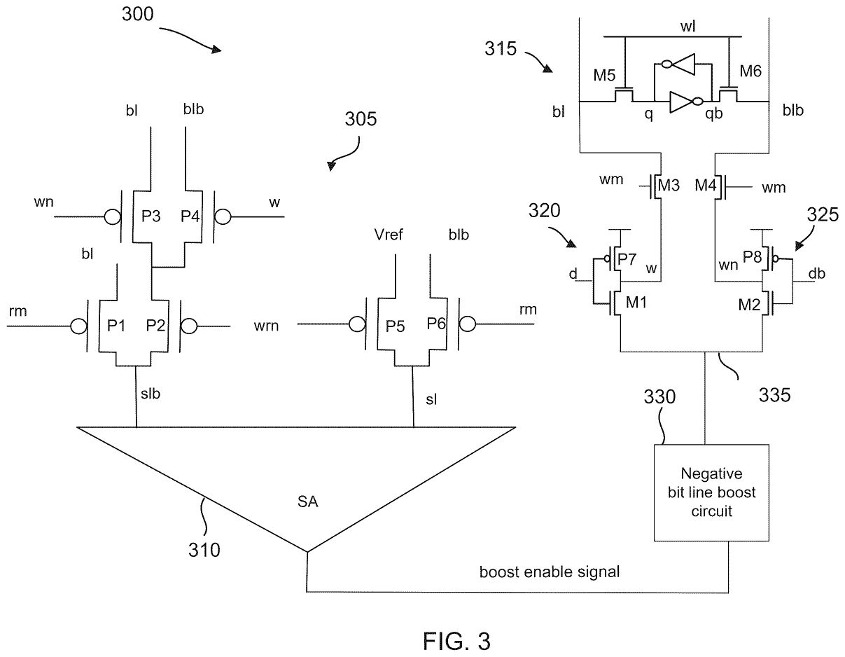

To avoid the die space demands of introducing a separate comparator to perform the comparison of the charged bit line voltage to the reference voltage, the selective negative bit line boost enable circuit disclosed herein may advantageously repurpose the read operation sense amplifier to perform the charged bit line voltage comparison to the reference voltage during write operations. An example memory 300 with a selective negative bit line boost enable circuit 305 that includes a sense amplifier 310 is shown in FIG. 3. It is advantageous for the sense amplifier 310 to be implemented as a charge-transfer sense amplifier as discussed further herein but it will be appreciated that any suitable sense amplifier architecture may be used in alternative implementations.

The memory 300 includes a plurality of columns of bitcells. Each column includes a pair of bit lines. For illustration clarity, only a single column is shown in FIG. 3 that is traversed by a bit line bl and a complement bit line blb. Similarly, only a single bitcell 315 is shown in FIG. 3 but it will be appreciated that each column may include a plurality of bitcells. The bitcells are arranged not only into columns but also into rows, with each row being traversed by a corresponding word line. For example, the bitcell 315 lies at the intersection of a word line wl and the bit lines bl and blb. A pair of cross-coupled inverters in the bitcell 315 drive a q node and a complement qb node. The word line wl couples to the gates of a pair of NMOS access transistors M5 and M6. When the word line wl voltage is charged to a memory power supply voltage, the access transistor M5 switches on so that bit line bl couples to the q node. Similarly, the access transistor M6 switches from the assertion of the word line wl voltage so that complement bit line blb couples to the qb node.

During a write operation, a write driver such as formed by an inverter 320 and an inverter 325 drive the bit line pair responsive to a data input signal d and a complement data input signal db. Just like the cross-coupled inverters in the bitcell 315, each inverter is formed by a serial pair of a PMOS transistor and an NMOS transistor. Inverter 320 thus includes a PMOS transistor P7 and an NMOS transistor M1 that function to invert the data input signal d into a write driver signal w that drives the bit line bl. If the data input signal d is a binary one (charged to the memory power supply voltage), the write signal w will thus be grounded. Similarly, the inverter 325 is formed by a serial pair of a PMOS transistor P8 and an NMOS transistor M2 that function to invert the complement data input signal into a complement write driver signal wn. If the data input signal d is a binary one, the complement write driver signal wn will also be a binary one.

A write column multiplexer includes an NMOS transistor M3 and an NMOS transistor M4 to select for the bit line pair bl and blb should a write column address signal wm be asserted. The voltage of the q node and the bit line bl will then equal the voltage of the write driver signal w. Similarly, the voltage of the complement qb node and the complement bit line blb will equal the voltage of the complement write driver signal wn. The write driver signals w and wn thus determine which one of the bit lines in the bit line pair that will be the charged bit line during a write operation. If the data input signal d is a binary one, the complement write driver signal will be a binary one such that the complement bit line blb is the charged bit line during a write operation. Conversely, the bit line bl is the charged bit line during a write operation if the data input signal d is a binary zero.

The selective negative bit line boost enable circuit 305 may thus use the write driver signals w and wn to select for and couple the charged bit line to the sense amplifier 310. An input node sl for the sense amplifier 310 may receive the reference voltage Vref during a write operation through a PMOS transistor P5 controlled by an active-low negative bit line boost timing signal wrn (note that an active-high timing signal may be used in alternative implementations). The negative bit line boost timing signal wrn is asserted during a negative bit line boost enable period portion of the write operation as will be discussed further herein. As defined herein, a binary signal is deemed to be “asserted” when the signal is logically true, regardless of whether an active-high or an active-low convention is used. An active-low signal is thus deemed herein to be asserted by being discharged to ground. Conversely, an active-high signal is deemed herein to be asserted by being charged to the memory power supply voltage. In a traditional memory with an always-enabled negative bit line boost operation, the assertion of the negative bit line boost timing signal wrn triggers the negative bit line boost. But in the selective negative bit line boost enable circuit 305, the assertion of the negative bit line boost timing signal wrn triggers instead the comparison at the sense amplifier 310 between the charged bit line voltage and the reference voltage Vref. Should a negative bit line boost be necessary, the selective negative bit line boost enable circuit 305 asserts the boost enable signal to trigger a negative bit line boost circuit 330 to apply a negative bit line boost to a negative bit line boost node 335. Should the data input signal d be a binary one, the negative bit line boost then couples through the transistors M1 and M3 in the write driver to pull the bit line and the q node to a negative voltage. Similarly, the negative bit line boost couples through the transistors M2 and M4 in the write driver to pull the complement bit line and the complement qb node to a negative voltage if the complement data input signal db is a binary one.

A set of three PMOS transistors P3, P4, and P2 functions to couple the charged bit line to a complement input node slb for the sense amplifier 310 during a write operation. The negative bit line boost timing signal wrn drive a gate of the transistor P2 so that it is on while the negative bit line boost timing signal wrn is asserted. The transistors P3 and P4 select for the charged bit line. In particular, the bit line bl couples to a source/drain terminal of the transistor P3 whereas a remaining source/drain terminal of the transistor P3 couples to a source/drain terminal of the transistor P2. The complement write driver signal wn drives a gate of the transistor P3. Since the complement write driver signal wn is discharged when the bit line bl is the charged bit line, transistor P3 switches on so that the bit line bl couples through transistors P3 and P2 to the input node slb when the negative bit line boost timing signal wrn is asserted. Similarly, the complement bit line blb couples to a source/drain terminal of the transistor P4 whereas a remaining source/drain terminal of the transistor P4 couples to the source/drain terminal of the transistor P2. The write driver signal w drives a gate of the transistor P4. Since the write driver signal w is discharged when the complement bit line blb is the charged bit line, transistor P4 switches on so that the complement bit line blb couples through transistors P4 and P2 to the input node slb when the negative bit line boost timing signal wrn is asserted. During a read operation, the bit line bl couples to the input node slb through a PMOS transistor P1 in response to an assertion of an active-low read multiplexer signal rm. Similarly, the complement bit line blb couples to the input node sl through a PMOS transistor P6 during a read operation in response to the assertion of the read multiplexer signal rm.

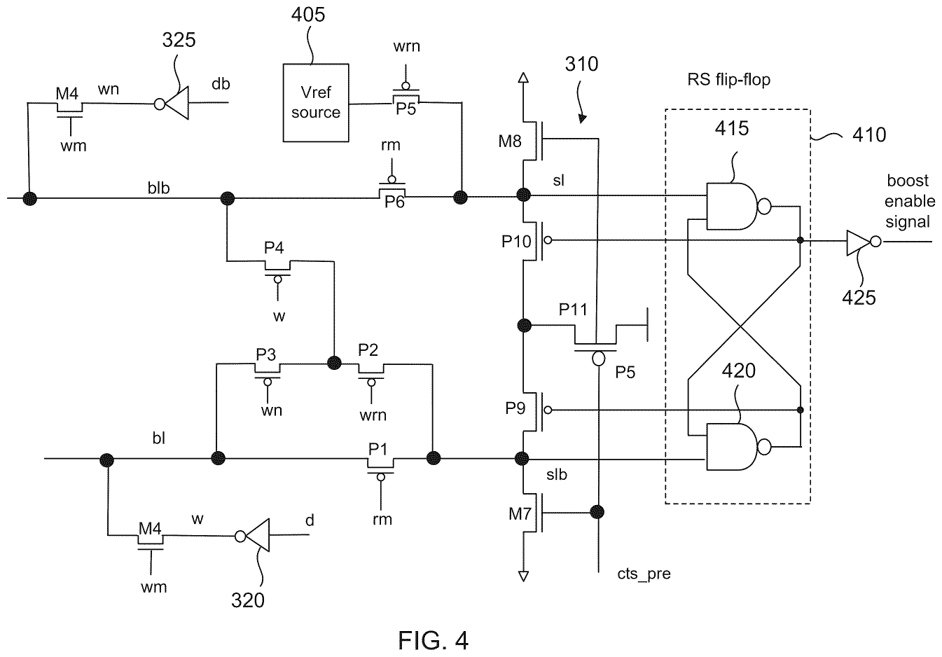

The selective negative bit line boost enable circuit 305 and the sense amplifier 310 are shown in more detail in FIG. 4. The transistors P1 through P6, write driver inverters 320 and 325, and write multiplexer transistors M3 and M4 are arranged as discussed for FIG. 3. A reference voltage source 405 provides the reference voltage Vref that couples through the transistor P5 when the negative bit line boost timing signal wrn is asserted. Since sense amplifier 310 is a charge-transfer sense amplifier, a reset-set (RS) latch 410 (which may also be denoted as an RS flip-flop) such as formed through a pair of cross-coupled NAND gates 415 and 420 may perform the comparison decision and latch the result. As part of the charge transfer sense amplifier operation, the input nodes sl and slb are discharged to ground in response to a pulsing high of a sense amplifier precharge signal cts_pre at during an earlier portion of a write operation. In particular, a drain of an NMOS transistor M7 couples to the input node slb whereas a source of transistor M7 couples to ground. The charge sharing signal cts_pre drives a gate of the transistor M7 so that the transistor M7 switches on to discharge the input node slb in response to the pulsing of the precharge signal cts_pre. Similarly, a drain of an NMOS transistor M8 couples to the input node slb whereas a source of the transistor M8 couples to ground. The pulsed precharge signal cts_pre drives a gate of the transistor M8 so that it switches on to discharge the input node sl.

The precharge signal cts_pre discharges to ground after it is pulsed so that the transistors M7 and M8 switch off. The precharge cts_pre also drives a gate of a PMOS transistor P11 having a source coupled to a node for the memory power supply voltage. A drain of the transistor P11 couples to a source of a PMOS transistor P10 and a source of a PMOS transistor P9. The drain of the transistor P9 couples to the input node slb. Similarly, the drain of the transistor P10 couples to the input node sl. An output terminal of the NAND gate 415 couples to a gate of the transistor P10. Similarly, an output terminal of the NAND gate 420 couples to a gate of the transistor P9. An inverter 425 inverts an output signal from the NAND gate 415 to provide the boost enable signal.

The output signals from the NAND gates 420 and 415 will each be a binary one after the pulsing of the precharge signal cts_pre since the NAND gates are NANDing the binary zeroes at the input nodes sl and slb. The boost enable signal will thus be a binary zero and transistors P10 and P9 will both be off after the pulsing of the precharge signal cts_pre. Depending upon the binary value of the data input signal d, one of the transistors P3 or P4 will be switched on during the write operation. But the transistor P2 will be off until the negative bit line boost timing signal wrn is pulsed low during the negative bit line boost enable period of the write operation. Similarly, transistor P5 will be off until the negative bit line boost timing signal wrn is pulsed low. Suppose that the charged one of the bit lines has a greater voltage than the reference voltage Vref. As the negative bit line boost timing signal discharges to ground according to a slew rate, the threshold voltage for transistor P2 will be satisfied before the threshold voltage of transistor P5 is satisfied. Transistor P2 will thus transfer charge from the charged bit line to the input node slb before any charge is transferred to the input node sl. Note that the capacitances of the input nodes sl and slb are relatively small compared to the bit line capacitances.

The transfer of charge from the charged bit line to the input node slb will thus quickly charge the input node slb to the charged bit line voltage (approximately the memory power supply voltage assuming that the ΔV of the charged bit line is relatively small). There is then a nearly full rail voltage difference between the input node sl and the input node slb such that a relatively low gain amplifier such as the RS latch 410 may be used to sense the input node voltage difference. The charging of the input node slb causes the output of the NAND gate 420 to discharge to ground. The cross-coupled NAND gates 420 and 415 will then latch the binary one at the output terminal of the NAND gate 415 such that the boost enable signal is not asserted, which is desirable since the voltage of the charged bit line was greater than the reference voltage Vref (ΔV of the charged bit line being relatively small). But suppose that the ΔV of the charged bit line is relatively large such that the charged bit line voltage is less than the reference voltage Vref as the negative bit line boost timing signal wrn discharges towards ground according to its slew rate. In that case, the threshold voltage of the transistor P5 will be satisfied before the threshold voltage of the transistor P2 is satisfied. Transistor P5 will then turn on before transistor P2 such that the input node sl is charged to the reference voltage before the charging of the input node slb. The charging of the input node sl causes the output signal of the NAND gate 415 to discharge to ground, which in turn causes the assertion of the negative bit line boost enable signal. A negative bit line boost is thus enabled, which is desirable due to the relatively large ΔV of the charged bit line. A similar charge transfer occurs during a read operation with respect to the switching on of either the transistor P1 or the transistor P6 as the read multiplexer signal RM slews towards ground.

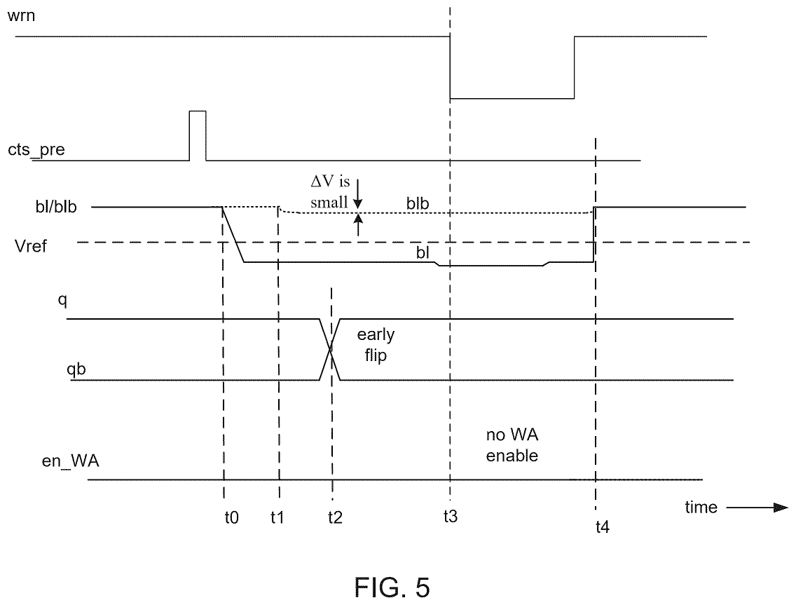

An early flip timing diagram for a write operation in memory 300 during which the negative bit line boost is suppressed is shown in FIG. 5. Prior to a write operation beginning at a time t0, a bit line bl and a complement bit line blb for an accessed column are both precharged to the memory power supply voltage. At time t0, a write driver (not illustrated) discharges the bit line bl while maintaining the charge of the complement bit line blb. The complement bit line blb is thus the charged bit line for this example. More generally, a first bit line in a bit line pair is discharged while a second bit line in the bit line pair is the charged bit line. At a time t1, a memory controller (not illustrated) asserts a word line (WL) voltage to switch on the access transistors to the accessed bitcell. In this example, it is assumed that the accessed bitcell is storing a binary zero prior to the write operation such that its complement bit node qb is grounded whereas its bit node q is charged to the memory power supply voltage. The discharged complement bit node qb thus causes a slight decrease ΔV in the complement bit line blb voltage after the word line voltage is asserted at time t1. Since the voltage difference between the q and qb nodes is nearly full rail (the difference being nearly equal to the power supply voltage), the write operation is successful (early flip) at a time t2 that is before the negative bit line boost timing signal wrn slews to ground at a time t3. Given that the voltage of the charged bit line (in this example, the complement bit line blb) is greater than the reference voltage Vref at time t3, the sense amplifier 310 (FIG. 3) does not assert the boost enable signal (en_WA). At a time t4, the write operation is completed so that the bit line bl and complement bit line blb are precharged to the memory power supply voltage.

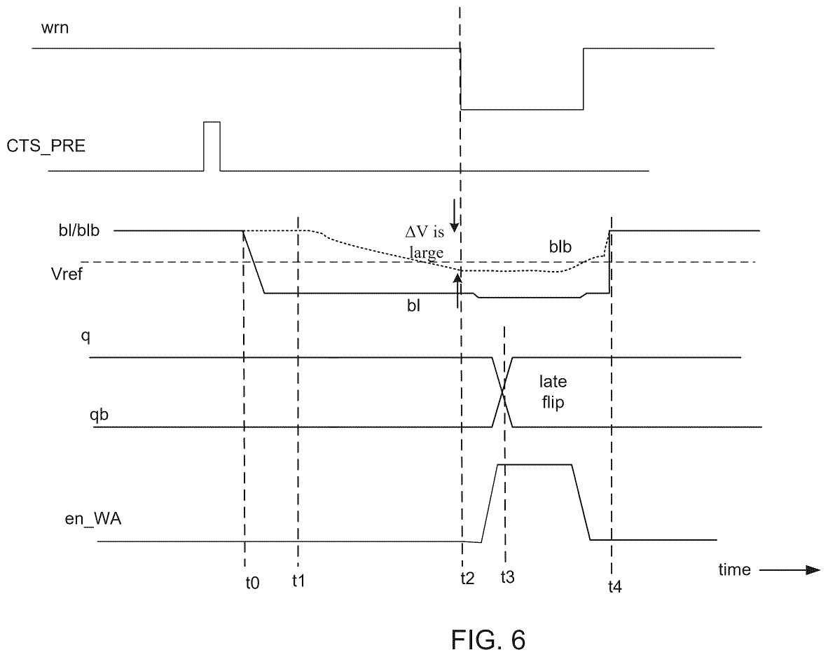

A late flip timing diagram for a write operation in memory 300 during which the negative bit line boost is enabled is shown in FIG. 6. Prior to a write operation beginning at a time t0, a bit line bl and a complement bit line blb for an accessed column are both precharged to the memory power supply voltage. At time t0, a write driver (not illustrated) discharges the bit line bl while maintaining the charge of the complement bit line blb. The complement bit line blb is thus again the charged bit line but this depends upon the binary value of the data input signal (not illustrated). At a time t1, the word line (WL) voltage is asserted (not illustrated) to switch on the access transistors to the accessed bitcell. In this example, it is again assumed that the accessed bitcell is storing a binary zero prior to the write operation such that its complement bit node qb is grounded whereas its bit node q is charged to the memory power supply voltage. But the discharged complement bit node qb causes a relatively large decrease ΔV in the complement bit line blb voltage after the word line voltage (not illustrated) is asserted at time t1. The resulting difference between the bit line bl voltage and the complement bit line voltage blb is thus relatively small such that the bitcell's binary content does not flip prior to the discharging of the negative bit line boost timing signal wrn at a time t2. The sense amplifier (not illustrated) then senses that the reference voltage Vref is greater than the charged bit line voltage, which causes the assertion of the boost enable signal en_WA approximately at time t2. The negative bit line boost then assists the write operation such that the bitcell's binary content has a binary transition at a time t3. At a time t4, the write operation is completed so that the bit line bl and complement bit line blb are pre-charged back to the memory power supply voltage.

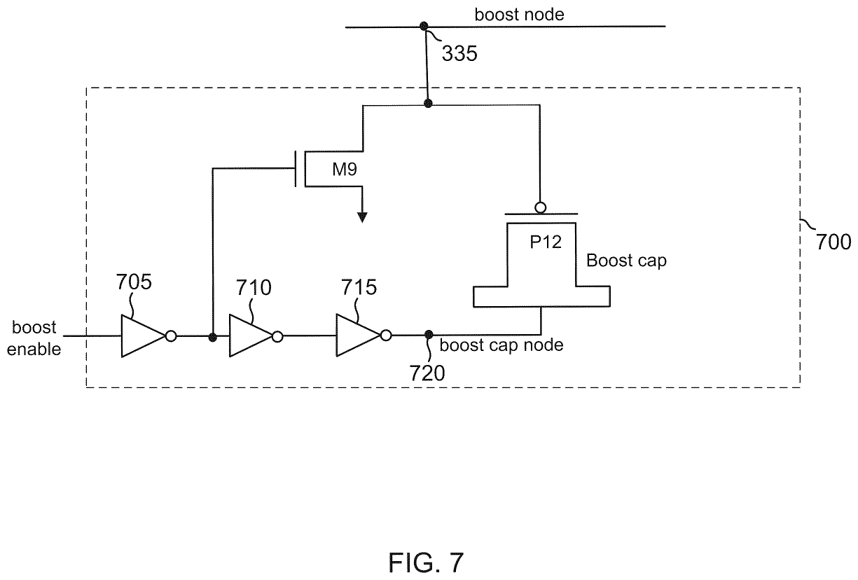

Referring again to FIG. 3. the negative bit line boost circuit 330 may be implemented using any suitable architecture as known in the negative bit line boost arts. An example negative bit line boost circuit 700 is shown in more detail in FIG. 7. A series of an odd-numbered plurality of inverters such as three inverters 705, 710, and 715 inverts the enable boost signal to drive a boost capacitor node (boost cap node) 720 at the drain and source of a PMOS transistor P12 that functions as a boost capacitor (boost cap). The output signal from the initial inverter 705 also drives a gate of an NMOS transistor having a source coupled to ground and a drain coupled to the boost node 335 (FIG. 3). The gate of the transistor P12 also is coupled to the boost node 335. Prior to the assertion of the boost enable signal, the transistor M9 is switched on to discharge the boost node 335. But the gate capacitance of the transistor P12 is then charged since its drain and source are charged to the memory power supply while its gate is discharged. At the assertion of the boost enable signal, the transistor M9 is switched off to float the boost node 335 while the boost cap node 720 is grounded. This grounding of the boost cap node 720 causes the charged gate capacitance of the transistor P12 to pull the boost node 335 to a negative bit line boost voltage.

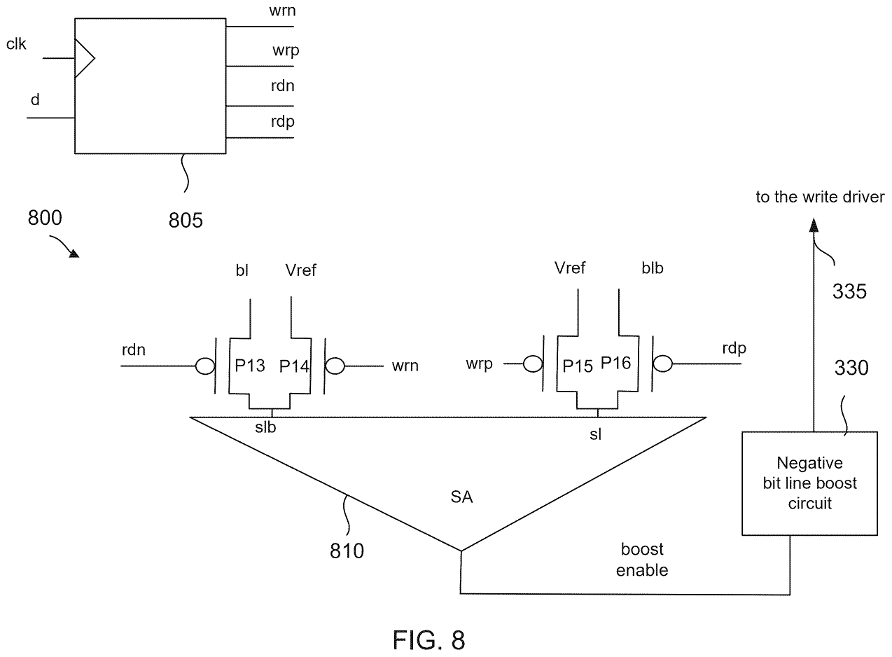

Referring again to FIGS. 3 and 4, it may be seen that if the bit line bl is the charged bit line, it couples through two transistors P3 and P2 so that the charged bit line voltage may be compared to the reference voltage by the sense amplifier 310. Similarly, if the complement bit line blb is the charged bit line, it couples through two transistors P4 and P2 so that the charged bit line voltage may be compared to the reference voltage Vref. A selective negative bit line boost enable circuit 800 is shown in FIG. 8 that also reuses a charge-transfer sense amplifier 810 but does not require the charged bit line to couple through two transistors to the input nodes of the sense amplifier 810. Depending upon the binary value of the data bit signal d, one of the input nodes sl and slb receives the charged bit line voltage whereas a remaining one of the sense amplifier nodes receives the reference voltage Vref. It is arbitrary which input node receives the charged bit line voltage but with the choice made, the remaining input node receives the reference voltage Vref. In the selective negative bit line boost enable circuit 800, the input node sl receives the complement bit line blb voltage while the input node slb receives the reference voltage Vref in response to the data input signal d being a binary one. Conversely, the input node slb receives the bit line bl voltage while the input node sl receives the reference voltage Vref in response to the data input signal d being a binary zero. To provide this routing flexibility, the read multiplexer signal rm may be bifurcated into a positive read multiplexer signal rdp and a negative read multiplexer signal rdn. Similarly, the negative bit line boost timing signal is bifurcated into an active-low first boost timing signal wrp and an active-low second boost timing signal wrn.

A memory controller 805 controls the signals wrp and wrn to be complementary to each other over the negative bit line boost enable period responsive to the binary value of the data input signal. For example, the memory controller may discharge the second boost timing signal wrn according a slew rate and maintain a charging of the first boost timing signal wrp to the memory power supply voltage during the negative bit line boost enable period in response to the data input signal d being a binary one such that it is the complement bit line blb that is the charged bit line during a write operation. Conversely, the memory controller 805 discharges the second boost timing signal wrn according to the slew rate during the negative bit line boost enable period in a write operation in which the data input signal d is a binary zero. The memory controller 805 maintains a charging of the first boost timing signal wrp to the memory power supply voltage in response to the data input signal d being a binary zero.

The first boost timing signal wrp drives a gate of a PMOS transistor P14 coupled between the input node slb and a node for the reference voltage Vref. Thus, the input node slb receives the reference voltage Vref during the negative bit line boost enable period in response to the first boost timing signal wrp slewing low enough to switch on the transistor P14 in a write operation in which the data input signal is a binary one. Similarly, the second boost timing signal wrn drives a gate of a PMOS transistor P15 coupled between the input node sl and the node for the reference voltage Vref. The input node sl thus receives the reference voltage Vref once the second boost timing signal wrn slews low enough to switch on the transistor P15 during the negative bit line boost enable period in a write operation in which the data input signal is a binary zero.

The memory controller 805 controls the positive read multiplexer signal rdp and the negative read multiplexer signal rdn analogously. In particular, the memory controller 805 discharges the positive read multiplexer signal rdp according to the slew rate and charges the negative read multiplexer signal rdp to the memory power supply voltage over the negative bit line boost enable period in response to the data input signal d being a binary one such that it is the complement bit line blb that is the charged bit line during a write operation. A PMOS transistor P16 couples between the input node sl and the bit line bl. The positive read multiplexer signal rdp drives a gate of the transistor P16 such that the transistor P16 eventually switches on once the positive read multiplexer signal rdp discharges sufficiently during the negative bit line boost enable period in a read operation in which the data input signal d is a binary one. Conversely, the memory controller 805 discharges the negative read multiplexer signal rdn and charges the positive read multiplexer rdp to the memory power supply voltage during the negative bit line boost enable period in a write operation in which the data input signal d is a binary zero. A PMOS transistor P13 couples between the input node slb and the complement bit line blb. The negative read multiplexer signal rdn drives a gate of the transistor P13 such that the transistor P13 eventually switches on once the negative read multiplexer signal rdn discharges sufficiently during the negative bit line boost enable period in a read operation in which the data input signal d is a binary zero. Note that the bit line bl couples through only the single transistor P13 to drive the input node slb. Similarly, the complement bit line blb couples through only the signal transistor P16 to drive the input node slb.

With the charged bit line voltage and the reference voltage Vref coupled to the sense amplifier 810 during the negative bit line boost enable period, the sense amplifier 810 may then assert the boost enable signal should the reference voltage Vref be greater than the charged bit line voltage. The negative bit line boost circuit 330 then applies a negative voltage boost to the negative bit line boost node 335 as discussed with respect to FIG. 7. Conversely, there is no application of a negative boost should the charged bit line voltage be greater than the reference voltage Vref.

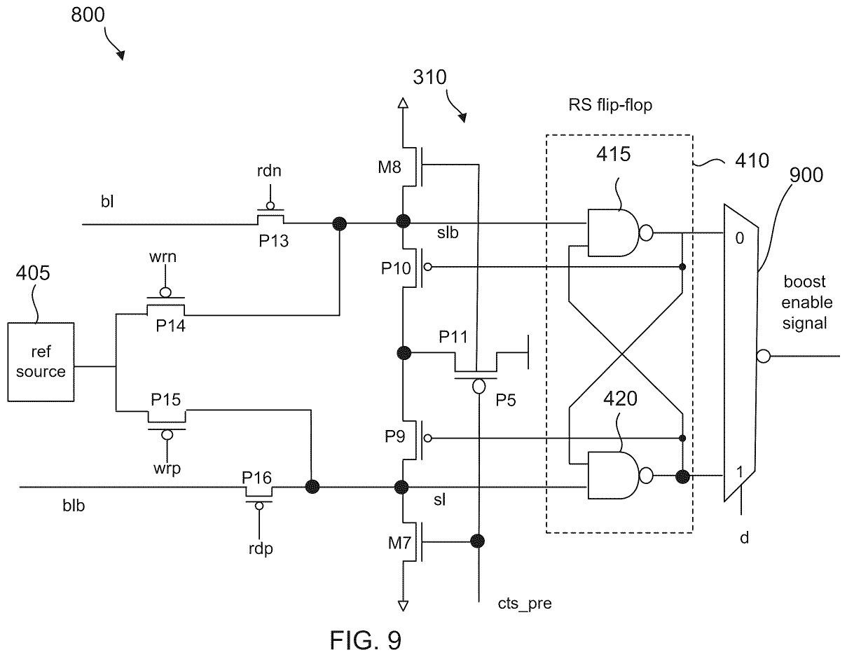

The selective negative bit line boost enable circuit 800 is shown in more detail in FIG. 9. The charge-transfer sense amplifier 810 includes the transistors M7, P9, P11, P10, and M8 arranged as discussed for the sense amplifier 310. In addition, the RS latch 410 including the cross-coupled logic gates such as the cross-coupled NAND gates 415 and 420 is also arranged as discussed with reference to the sense amplifier 310. The reference voltage source 405 couples to a source of the transistors P14 and P15 to provide the reference voltage Vref. The transistors P13, P14, P15, and P16 are arranged as discussed for FIG. 8. Since the input nodes sl and slb are relatively low capacitance as compared to the bit line capacitance and the capacitance of the reference voltage source 405, the charge transfer will occur to the discharged input nodes as discussed with respect to FIG. 4. Through the resulting charge transfer, the sense amplifier 810 may use the RS latch 410 as also discussed with respect to FIG. 4. But in the sense amplifier 810, the boost enable signal is selectively derived from the output signal of either the NAND gate 415 or the NAND gate 420 depending upon the binary value of the data input signal d. To perform the selection, an inverting multiplexer 900 selects for the output signal from NAND gate 415 in response to the data input signal d being a binary one during the write operation. Similarly, the inverting multiplexer 900 selects for the output signal from the NAND gate 420 in response to the data input signal d being a binary zero during the write operation.

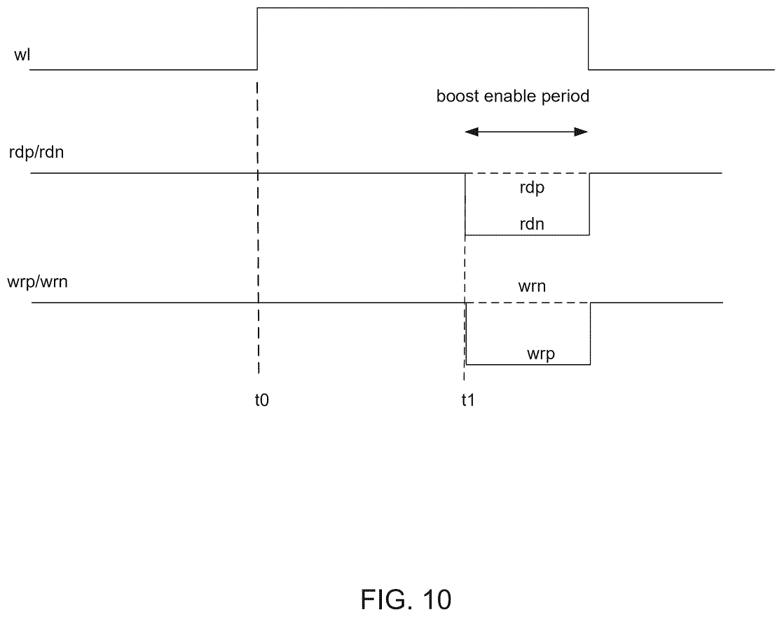

An example timing diagram for the read multiplexer signals rdn and rdp, the first boost timing signal wrp, and the second boost timing signal wrn is shown in FIG. 10. In this example, the data input signal d is assumed to be a binary zero. During a write operation, the word line voltage wl is asserted at a time t1. After a self-timed delay such as controlled by the memory controller 805, the negative bit line boost enable period begins at a time t1 with the discharging of the negative read multiplexer signal rdn and the positive boost signal wrp. If the reference voltage Vref is less than the charged bit line voltage (which in this example would be the bit line bl voltage), the transistor P13 of FIG. 9 will switch on before the transistor P15 switches on. The RS latch will then latch so that the boost enable signal remains discharged. But if the reference voltage Vref is greater than the complement bit line blb voltage, transistor P15 will switch on before transistor P13. The input node sl will then charge towards the memory power supply voltage, which causes the RS latch 410 to latch such that the boost enable signal is asserted to the memory power supply voltage analogously as discussed for the sense amplifier 310. The positive read multiplexer signal rdp and the negative boost signal wrn both remain charged to the memory power supply voltage during the negative bit line boost enable period such that the transistors P14 and P16 remain off.

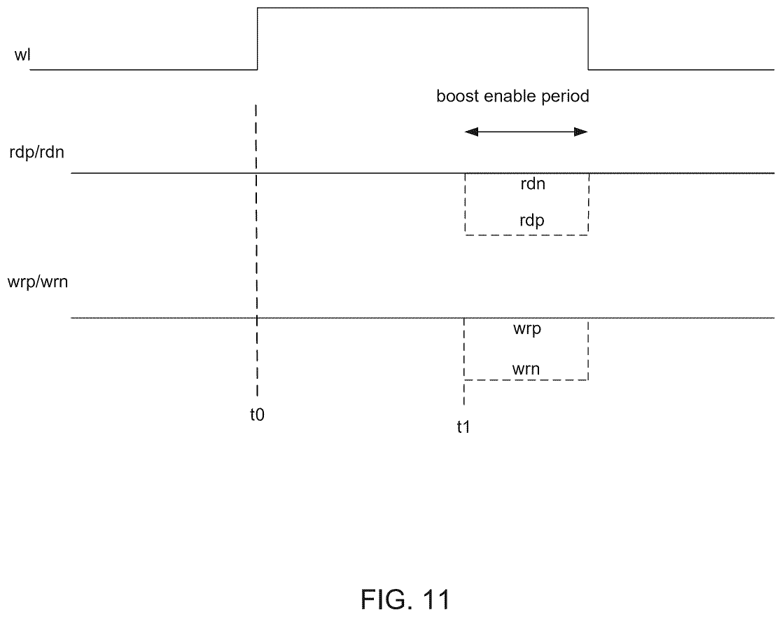

Another example timing diagram for the read multiplexer signals rdn and rdp, the first boost timing signal wrp, and the second boost timing signal wrn is shown in FIG. 11. In this example, the data input signal d is assumed to be a binary one. During a write operation, the word line voltage wl is asserted at a time t1. After a self-timed delay such as controlled by the memory controller 805, the negative bit line boost enable period begins with the discharging of the positive read multiplexer signal rdp and the negative boost signal wrn. If the reference voltage Vref is less than the charged bit line voltage (which in this example would be the complement bit line blb voltage), the transistor P16 of FIG. 9 will switch on before the transistor P14 switches on. The RS latch will then latch so that the boost enable signal remains discharged. But if the reference voltage Vref is greater than the bit line bl voltage, transistor P14 will switch on before transistor P16. The complement sense amplifier node slb will then charge towards the memory power supply voltage, which causes the RS latch 410 to latch such that the boost enable signal is asserted to the memory power supply voltage analogously as discussed for the sense amplifier 310. The negative read multiplexer signal rdn and the positive boost timing signal wrp both remain charged to the memory power supply voltage during the negative bit line boost enable period such that the transistors P13 and P15 remain off.

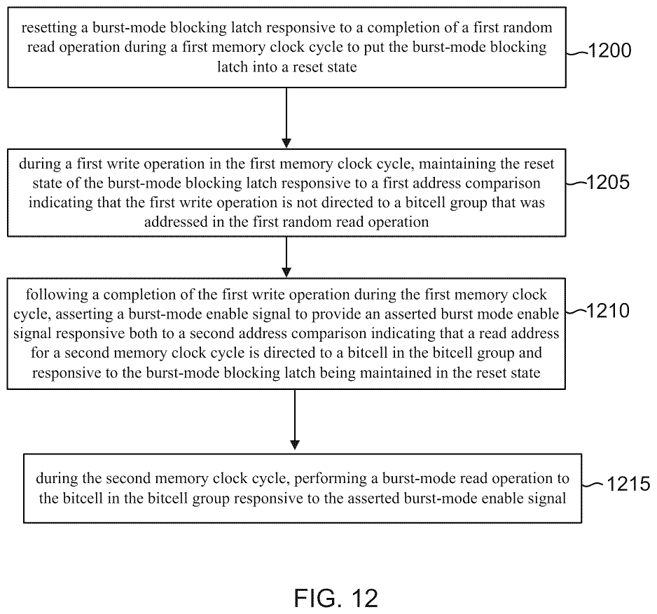

A selective negative bit line boost method of operation for memory will now be discussed with regard to the flowchart of FIG. 12. The method includes an act 1200 of charging a first bit line in a bit line pair through a write driver during a write operation while discharging a second bit line in the bit line pair through the write driver. The charging of either the bit line or the complement bit line in the bit line pair of FIGS. 3, 4, 8, and 9 while the remaining bit line is discharged is an example of act 1200. The method also includes an act 1205 of asserting a boost enable signal during a negative boost enable period of the write operation responsive to a voltage of the first bit line being less than a reference voltage. The assertion of the boost enable signal as discussed with regard to FIG. 2 is an example of act 1205. Finally, the method includes an act 1210 of applying a negative voltage to the second bit line during the negative boost enable period responsive to the asserting of the boost enable signal. The negative bit line boost as discussed with regard to FIG. 7 is an example of act 1210.

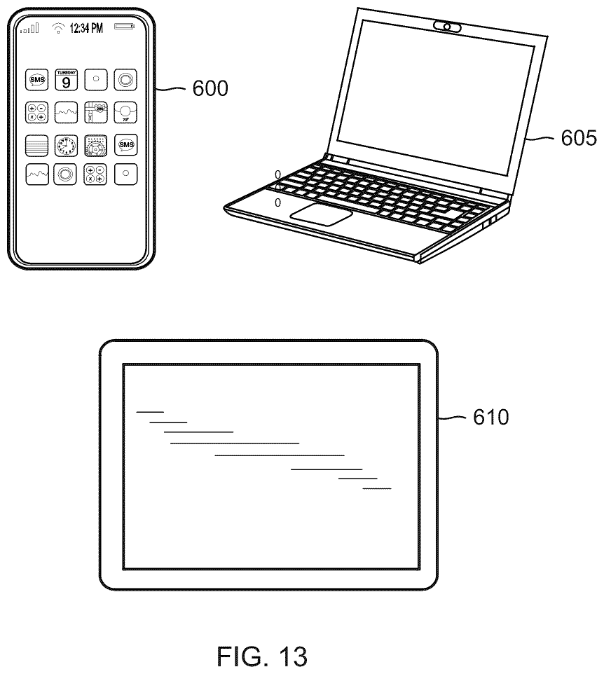

A memory with selective application of a negative bit line boost as disclosed herein may be incorporated into a wide variety of electronic systems. For example, as shown in FIG. 13, a cellular telephone 1300, a laptop computer 1305, and a tablet PC 1310 may all include a memory with a selective negative bit line boost in accordance with the disclosure. Other exemplary electronic systems such as a music player, a video player, a communication device, and a personal computer may also be configured with memories constructed in accordance with the disclosure.

Some aspects of the disclosure will now be summarized in the following series of example clauses:
Clause 1. A memory, comprising:
a column of bitcells including a bit line and a complement bit line;
a write driver configured to drive the bit line and the complement bit line responsive to a data input signal;
a negative bit line boost circuit configured to charge a negative boost node of the write driver to a negative voltage responsive to an assertion of a boost enable signal; and
a sense amplifier configured to assert the boost enable signal responsive to a voltage of a charged one of the bit line and the complement bit line having less than a threshold voltage decrease during a write operation, the sense amplifier being further configured to not assert the boost enable signal responsive to the voltage of the charged one of the bit line and the complement bit line having greater than the threshold voltage decrease during the write operation.
Clause 2. The memory of clause 1, further comprising:
a reference voltage source configured to provide a reference voltage, wherein the sense amplifier is further configured to compare the voltage of the charged one of the bit line and the complement bit line to the reference voltage to determine whether the voltage of the charged one of the bit line and the complement bit line has declined more than the threshold voltage decrease.
Clause 3. The memory of clause 2, wherein the sense amplifier includes a first input node and a second input node, and wherein the write driver is configured to invert the data input signal into a write driver signal and to invert a complement of the data input signal into a complement write driver signal, the sense amplifier further comprising:
a memory controller configured to assert a write multiplexer signal during a boost enable period of the write operation;
a first transistor coupled between the first input node and the reference voltage source and having a gate coupled to the write multiplexer signal;
a second transistor having a first terminal coupled to the bit line and having a gate coupled to the complement write driver signal;
a third transistor having a first terminal coupled to the complement bit line and having a second terminal coupled to a second terminal of the second transistor and having a gate coupled to the write driver signal; and
a fourth transistor coupled between the second input node and the second terminal of the second transistor and having a gate coupled to the write multiplexer signal.
Clause 4. The memory of clause 3, wherein the memory controller is further configured to assert a read multiplexer signal during a read operation, the memory further comprising:
a fifth transistor coupled between the bit line and the second input node and having a gate coupled to the read multiplexer signal; and
a sixth transistor coupled between the complement bit line and the first input node and having a gate coupled to the read multiplexer signal.
Clause 5. The memory of clause 4, wherein the first transistor, the second transistor, the third transistor, the fourth transistor, the fifth transistor, and the sixth transistor each comprises a p-type metal-oxide semiconductor (PMOS) transistor.
Clause 6. The memory of any of clauses 1-5, wherein the sense amplifier includes a reset-set latch.
Clause 7. The memory of clause 6, wherein the reset-set latch comprises a pair of cross-coupled NAND gates.
Clause 8. The memory of clause 7, further comprising:
a sense amplifier precharge circuit configured to ground a first input node and a second input node of the sense amplifier during an initial portion of the write operation.
Clause 9. The memory of any of clauses 1-8, wherein the negative bit line boost circuit is configured to charge the negative boost node of the write driver to the negative voltage responsive to a charged gate capacitance of a transistor.
Clause 10. The memory of clause 1, wherein the memory is included within an integrated circuit.
Clause 11. The memory of clause 10, wherein the integrated circuit is included within a cellular telephone.
Clause 12. A selective negative bit line boost method, comprising:
charging a first bit line in a bit line pair through a write driver during a write operation while discharging a second bit line in the bit line pair through the write driver;
asserting a boost enable signal during a negative boost enable period of the write operation responsive to a voltage of the first bit line being less than a reference voltage; and
applying a negative voltage to the second bit line during the negative boost enable period responsive to the asserting of the boost enable signal.
Clause 13. The selective negative bit line boost method of clause 12, further comprising:
de-asserting the boost enable signal during the negative boost enable period of the write operation responsive to the voltage of the first bit line being greater than the reference voltage; and
preventing a negative bit line boost to the second bit line during the negative boost enable period responsive to the de-asserting of the boost enable signal.
Clause 14. The selective negative bit line boost method of any of clauses 12-13, further comprising:
comparing a voltage of the first bit line to the reference voltage in a sense amplifier; and
inverting an output signal of the comparator to assert the boost enable signal.
Clause 15. The selective negative bit line boost method of clause 14, further comprising:
sensing a bit through the sense amplifier during a read operation.
Clause 16. A memory, comprising:
a bit line pair including a first bit line and a second bit line;
a sense amplifier having a first input node and a second input node;
a reference voltage source;
a first transistor coupled between the reference voltage source and the first input node;
a second transistor coupled between the reference voltage source and the second input node;
a third transistor coupled between the first bit line and the first input node; and
a fourth transistor coupled between the second bit line and the second input node.
Clause 17. The memory of clause 16, further comprising:
a write driver configured to drive the first bit line and the second bit line responsive to a data input signal; and
a negative bit line boost circuit configured to charge a negative boost node of the write driver to a negative voltage responsive to an assertion of a boost enable signal from the sense amplifier.
Clause 18. The memory of clause 17, wherein the sense amplifier includes a cross-coupled pair of logic gates and includes an inverting multiplexer configured to select from a pair of output signals from the pair of cross-coupled logic gates to provide the boost enable signal.
Clause 19. The memory of clause 18, wherein the pair of cross-coupled logic gates comprises a pair of NAND gates.
Clause 20. The memory of any of clauses 16-19, wherein the first transistor, the second transistor, the third transistor, and the fourth transistor each comprises a PMOS transistor.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A memory, comprising:
a column of bitcells including a bit line and a complement bit line;
a write driver configured to drive the bit line and the complement bit line responsive to a data input signal;
a negative bit line boost circuit configured to charge a negative boost node of the write driver to a negative voltage responsive to an assertion of a boost enable signal; and
a sense amplifier configured to assert the boost enable signal responsive to a voltage of a charged one of the bit line and the complement bit line having less than a threshold voltage decrease during a write operation, the sense amplifier being further configured to not assert the boost enable signal responsive to the voltage of the charged one of the bit line and the complement bit line having greater than the threshold voltage decrease during the write operation.

2. The memory of claim 1, further comprising:
a reference voltage source configured to provide a reference voltage, wherein the sense amplifier is further configured to compare the voltage of the charged one of the bit line and the complement bit line to the reference voltage to determine whether the voltage of the charged one of the bit line and the complement bit line has declined more than the threshold voltage decrease.

3. The memory of claim 2, wherein the sense amplifier includes a first input node and a second input node, and wherein the write driver is configured to invert the data input signal into a write driver signal and to invert a complement of the data input signal into a complement write driver signal, the sense amplifier further comprising:
a memory controller configured to assert a write multiplexer signal during a boost enable period of the write operation;
a first transistor coupled between the first input node and the reference voltage source and having a gate coupled to the write multiplexer signal;
a second transistor having a first terminal coupled to the bit line and having a gate coupled to the complement write driver signal;
a third transistor having a first terminal coupled to the complement bit line and having a second terminal coupled to a second terminal of the second transistor and having a gate coupled to the write driver signal; and
a fourth transistor coupled between the second input node and the second terminal of the second transistor and having a gate coupled to the write multiplexer signal.

4. The memory of claim 3, wherein the memory controller is further configured to assert a read multiplexer signal during a read operation, the memory further comprising:
a fifth transistor coupled between the bit line and the second input node and having a gate coupled to the read multiplexer signal; and
a sixth transistor coupled between the complement bit line and the first input node and having a gate coupled to the read multiplexer signal.

5. The memory of claim 4, wherein the first transistor, the second transistor, the third transistor, the fourth transistor, the fifth transistor, and the sixth transistor each comprises a p-type metal-oxide semiconductor (PMOS) transistor.

6. The memory of claim 1, wherein the sense amplifier includes a reset-set latch.

7. The memory of claim 6, wherein the reset-set latch comprises a pair of cross-coupled NAND gates.

8. The memory of claim 7, further comprising:
a sense amplifier precharge circuit configured to ground a first input node and a second input node of the sense amplifier during an initial portion of the write operation.

9. The memory of claim 1, wherein the negative bit line boost circuit is configured to charge the negative boost node of the write driver to the negative voltage responsive to a charged gate capacitance of a transistor.

10. The memory of claim 1, wherein the memory is included within an integrated circuit.

11. The memory of claim 10, wherein the integrated circuit is included within a cellular telephone.

12. A selective negative bit line boost method, comprising:
charging a first bit line in a bit line pair through a write driver during a write operation while discharging a second bit line in the bit line pair through the write driver;
asserting a boost enable signal during a negative boost enable period of the write operation responsive to a voltage of the first bit line being less than a reference voltage; and
applying a negative voltage to the second bit line during the negative boost enable period responsive to the asserting of the boost enable signal.

13. The selective negative bit line boost method of claim 12, further comprising:
de-asserting the boost enable signal during the negative boost enable period of the write operation responsive to the voltage of the first bit line being greater than the reference voltage; and
preventing a negative bit line boost to the second bit line during the negative boost enable period responsive to the de-asserting of the boost enable signal.

14. The selective negative bit line boost method of claim 12, further comprising:
comparing a voltage of the first bit line to the reference voltage in a sense amplifier; and
inverting an output signal of the comparator to assert the boost enable signal.

15. The selective negative bit line boost method of claim 14, further comprising:
sensing a bit through the sense amplifier during a read operation.

16. A memory, comprising:
a bit line pair including a first bit line and a second bit line;
a sense amplifier having a first input node and a second input node;
a reference voltage source;
a first transistor coupled between the reference voltage source and the first input node;
a second transistor coupled between the reference voltage source and the second input node;
a third transistor coupled between the first bit line and the first input node; and
a fourth transistor coupled between the second bit line and the second input node.

17. The memory of claim 16, further comprising:
a write driver configured to drive the first bit line and the second bit line responsive to a data input signal; and
a negative bit line boost circuit configured to charge a negative boost node of the write driver to a negative voltage responsive to an assertion of a boost enable signal from the sense amplifier.

18. The memory of claim 17, wherein the sense amplifier includes a cross-coupled pair of logic gates and includes an inverting multiplexer configured to select from a pair of output signals from the pair of cross-coupled logic gates to provide the boost enable signal.

19. The memory of claim 18, wherein the pair of cross-coupled logic gates comprises a pair of NAND gates.

20. The memory of claim 16, wherein the first transistor, the second transistor, the third transistor, and the fourth transistor each comprises a PMOS transistor.
